(19) United States
(12) Patent Application Publication
(10) Pub. No.: US 2020/0127039 A1
(43) Pub. Date: Apr. 23, 2020

(54) LIGHT-RECEIVING DEVICE, METHOD OF MANUFACTURING LIGHT RECEIVING DEVICE, IMAGING DEVICE, AND ELECTRONIC APPARATUS

(71) Applicant: SONY SEMICONDUCTOR SOLUTIONS CORPORATION, Kanagawa (JP)

(72) Inventors: Suguru SAITO, Kanagawa (JP); Nobutoshi FUJII, Kanagawa (JP)

(73) Assignee: SONY SEMICONDUCTOR SOLUTIONS CORPORATION, Kanagawa (JP)

(21) Appl. No.: 16/477,969

(22) PCT Filed: Dec. 19, 2017
(86) PCT No.: PCT/JP2017/045422

§ 371 Date: Jul. 15, 2019

(30) Foreign Application Priority Data
Jan. 24, 2017 (JP) 2017-010187

(51) Int. Cl. H01L 27/146; H04N 5/33

(52) U.S. Cl. CPC H01L 27/14669; H04N 5/33; H01L 27/14683

(57) ABSTRACT

There is provided a light-receiving device including: a plurality of photoelectric conversion layers including a first photoelectric conversion layer and a second photoelectric conversion layer disposed in respective regions that are different in a planar view; an insulating film that separates the plurality of photoelectric conversion layers from one another; a first inorganic semiconductor material included in the first photoelectric conversion layer; and a second inorganic semiconductor material included in the second photoelectric conversion layer, and different from the first inorganic semiconductor material.

### TECHNICAL FIELD

The present disclosure relates to a light-receiving device to be used, for example, for an infrared sensor, etc. and a method of manufacturing the same, and to an imaging device and an electronic apparatus.

### BACKGROUND ART

In recent years, an image sensor (an infrared sensor) having sensitivity in an infrared region has been commercialized. For example, as described in PTL 1, in a light-receiving device used for this infrared sensor, a photoelectric conversion layer including, for example, a Group III-V semiconductor such as InGaAs (indium gallium arsenide) is used, and in this photoelectric conversion layer, electric charges are generated (photoelectric conversion is performed) by absorption of an infrared ray.

### CITATION LIST

### Patent Literature

PTL 1: Japanese Unexamined Patent Application Publication No. 2014-127499

### SUMMARY OF THE INVENTION

As for a device structure of such a light-receiving device or an imaging device, various proposals have been made, but it is expected to further widen a photoelectrically convertible wavelength band.

It is therefore desirable to provide a light-receiving device, a method of manufacturing the light-receiving device, an imaging device, and an electronic apparatus that make it possible to perform photoelectric conversion in a wide wavelength hand.

A light-receiving device according to an embodiment of the present disclosure includes: a plurality of photoelectric conversion layers including a first photoelectric conversion layer and a second photoelectric conversion layer disposed in respective regions that are different in a planar view; an insulating film that separates the plurality of photoelectric conversion layers from one another; a first inorganic semiconductor material included in the first photoelectric conversion layer; and a second inorganic semiconductor material included in the second photoelectric conversion layer, and different from the first inorganic semiconductor material.

A method of manufacturing a light-receiving device according to an embodiment of the present disclosure includes: of a plurality of photoelectric conversion layers disposed in respective regions that are different in a planar view, and separated from one another by an insulating film, forming a first photoelectric conversion layer including a first inorganic semiconductor material; and forming a second photoelectric conversion layer including a second inorganic semiconductor material different from the first inorganic semiconductor material.

According to the light-receiving device and the method of manufacturing the light-receiving device of the respective embodiments, the first photoelectric conversion layer and the second photoelectric conversion layer include the inorganic semiconductor materials different from each other (the first inorganic semiconductor material and the second inorganic semiconductor material); therefore, photoelectrically convertible wavelength is set in each of the first photoelectric conversion layer and the second photoelectric conversion layer.

An imaging device according to an embodiment of the present disclosure includes the above-described light-receiving device according to the embodiment of the present disclosure.

An electronic apparatus according to an embodiment of the present disclosure includes the above-described imaging device according to the embodiment of the present disclosure.

According to the light-receiving device, the method of manufacturing the light-receiving device, the imaging device, and the electronic apparatus of the respective embodiments of the present disclosure, the first photoelectric conversion layer and the second photoelectric conversion layer include the inorganic semiconductor materials different from each other, which makes it possible to shift photoelectrically convertible wavelengths of the first photoelectric conversion layer and the second photoelectric conversion layer. This makes it possible to perform photoelectric conversion in a wide wavelength band.

It is to be noted that contents described above are illustrative. Effects to be achieved by the present disclosure are not limited to effects described above, and may be effects other than those described above, or may further include other effects in addition to those described above.

### BRIEF DESCRIPTION OF DRAWINGS

FIG. 1 is a cross-sectional view of a configuration of a light-receiving device according to an embodiment of the present disclosure.

FIG. 2A is a cross-sectional view for description of one process of a method of manufacturing the light-receiving device illustrated in FIG. 1.

FIG. 2B is a cross-sectional view of a process following FIG. 2A.

FIG. 2C is a cross-sectional view of a process following FIG. 2B.

FIG. 2D is a cross-sectional view of a process following FIG. 2C.

FIG. 2E is a cross-sectional view of a process following FIG. 2D.

FIG. 3A is a cross-sectional view of a process following FIG. 2E.

FIG. 3B is a cross-sectional view of a process following FIG. 3A.

FIG. 3C is a cross-sectional view of a process following FIG. 3B.

FIG. 4 is a cross-sectional view of a configuration of a light-receiving device according to a comparative example.

FIG. 5A is a cross-sectional view for description of one process of a method of manufacturing the light-receiving device illustrated in FIG. 4.

FIG. 5B is a cross-sectional view of a. process following FIG. 5A.

FIG. 5C is a cross-sectional view of a process following FIG. 5B.

FIG. 6 is a cross-sectional view of a configuration of a light-receiving device according to a modification example 1.

FIG. 7 is a cross-sectional view of a configuration of a light-receiving device according to a modification example 2.

FIG. 8 is a cross-sectional view of another example of the light-receiving device illustrated in FIG. 7.

FIG. 9A is a cross-sectional view for description of one process of a method of manufacturing the light-receiving device illustrated in FIG. 7.

FIG. 9B is a cross-sectional view of a process following FIG. 9A.

FIG. 9C is a cross-sectional view of a process following FIG. 9B.

FIG. 10A is a cross-sectional view of a process following FIG. 9C

FIG. 10B is a cross-sectional view of a process following FIG. 10A.

FIG. 10C is a cross-sectional view of a process following FIG. 10B.

FIG. 11 is a cross-sectional view of a configuration of a light-receiving device according to a modification example 3.

FIG. 12 is a cross-sectional view for description of one process of a method of manufacturing the light-receiving device illustrated in FIG. 11.

FIG. 13 is a cross-sectional view for description of an operation of the light-receiving device illustrated in FIG. 11.

FIG. 14 is a block diagram illustrating a configuration of an imaging device.

FIG. 15 is a schematic diagram illustrating a configuration example of an imaging device of a stacked type.

FIG. 16 is a functional block diagram illustrating an example of an electronic apparatus (a camera)using the imaging device illustrated in FIG. 14.

FIG. 17 is a view depicting an example of a schematic configuration of an endoscopic surgery system.

FIG. 18 is a block diagram depicting an example of a functional configuration of a camera head and a camera control unit (CCU).

FIG. 19 is a block diagram depicting an example of schematic configuration of a vehicle control system,

FIG. 20 is a diagram of assistance in explaining an example of installation positions of an outside-vehicle information detecting section and an imaging section.

### MODES FOR CARRYING OUT THE INVENTION

Some embodiments of the present disclosure are described below in detail with reference to the drawings. It is to be noted that the description is given in the following order.
1. Embodiment (An example of a light-receiving device including a photoelectric conversion layer that includes inorganic semiconductor materials different from each other)
2. Modification Example 1 (An example including photoelectric conversion layers different in size from each other in a planar view)
3. Modification Example 2 (An example in which a light incident surface is flat)
4. Modification Example 3 (An example of light dispersion in a longitudinal direction)
5. Application Example 1 (An example of an imaging device)
6. Application Example 2 (An example of an electronic apparatus)
7. Further Application Example 1 (A further application example to an endoscopic surgery system)
8. Further Application Example 2 (A further application example to a mobile body)

### EMBODIMENT

### [Configuration]

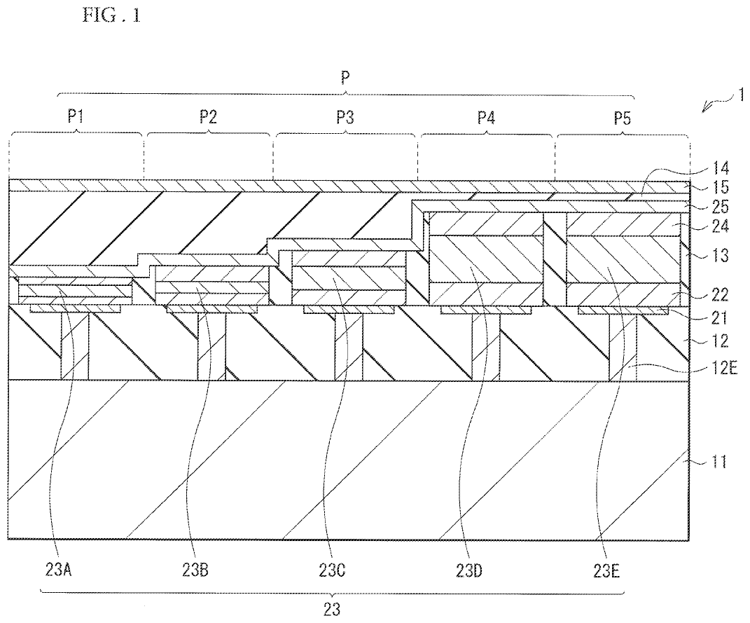

FIG. 1 illustrates a cross-sectional configuration of a light-receiving device (a light-receiving device 1) of an embodiment of the present disclosure. The light-receiving device 1 is applied, for example, to an infrared sensor, etc. using an inorganic semiconductor material such as a Group III-V semiconductor, and includes a plurality of light-receiving unit regions P (pixels P1, P2, P3, P4, P5, . . . Pn) two-dimensionally arranged, for example. It is to be noted that FIG. 1 illustrates a cross-sectional configuration of a portion corresponding to five pixels P (the pixels P1 to P5).

The light-receiving device 1 includes a ROTC (readout integrated circuit) substrate 11. In the light-receiving device 1, a first electrode 21, a first contact layer 22, a photoelectric conversion layer 23, a second contact layer 24, and a second electrode 25 are provided in this order on this ROIC substrate 11. The first electrode 21, the first contact layer 22, the photoelectric conversion layer 23, and the second contact layer 24 are provided separately for each of the pixels P, and the second electrode 25 is provided common to the plurality of pixels P. In the light-receiving device 1, light (e.g., light of wavelengths in a visible region and an infrared region) incident on the photoelectric conversion layer 23 from side of the second electrode 25. For example, light of a wavelength in the visible region is photoelectrically converted in each of the pixels P1 to P3, and light of a wavelength in the infrared region is photoelectrically converted in each of the pixels P4 and PS.

The light-receiving device 1 includes a protective film 12 between the first electrode 21 and the ROTC substrate 11, and the protective film 12 is provided with a through electrode 12E coupled to the first electrode 21. The light-receiving device 1 includes an insulating film 13 between adjacent ones of the pixels P. The light-receiving device 1 includes a passivation film 14 and a color filter layer 15 in this order on the second electrode 25, and in the light-receiving device 1, light having passed through the color filter layer 15 and the passivation film 14 is incident on the photoelectric conversion layer 23. A configuration of each portion is described below. It is to be noted that the pixels P1 to P5 have similar configurations except for the photoelectric conversion layer 23, and the description of each portion except for the photoelectric conversion layer 23 is thus common to the respective pixels P.

The ROIC substrate 11 includes, for example, a silicon (Si) substrate and a multilayered wiring layer disposed. on the silicon substrate, and this multilayered wiring layer is provided with an ROIC. In the multilayered wiring layer, at a position close to the protective film 12, an electrode including, for example, copper (Cu) is provided for each of the pixels P, and this electrode is in contact with the through electrode 12E.

The first electrode 21 serves as an electrode (anode) that is supplied with a voltage for readout of signal charges (holes or electrons; hereinafter described as holes for convenience) generated in the photoelectric conversion layer 23, and is provided for each of the pixels P. The first electrode 21 is smaller than the first contact layer 22 in a planar view, and is in contact with a substantially central portion of the first contact layer 22. One first electrode 21 is disposed for a corresponding one of the pixels P. and the first electrodes 21 in adjacent ones of the pixels P are electrically separated from each other by the protective film 12.

The first electrode 21 includes, for example, a simple substance of any of titanium (Ti), tungsten (W), titanium nitride (TiN), platinum (Pt), gold (Au), germanium (Ge), palladium (Pd), zinc (Zn), nickel (Ni), and aluminum (Al), or an alloy including at least one of these materials. The first electrode 21 may include a single layer film of any of the above-described constituent materials, or may include a stacked film including a combination of two or more of the above-described constituent materials.

The first contact layer 22 is provided between the first electrode 21 and the photoelectric conversion layer 23, and is in contact with the first electrode 21 and the photoelectric conversion layer 23. One first contact layer 22 is disposed for a corresponding one of the pixels P, and the first contact layers 22 in adjacent ones of the pixels P are electrically separated from each other by the insulating film 13. The first contact layer 22 serve as a region where the signal charges generated in the photoelectric conversion layer 23 move, and includes, for example, an inorganic semiconductor material including a p-type impurity. For example, it possible to use InP (indium phosphide) including a p-type impurity such as Zn (zinc), for the first contact layer 22. For example, the first contact layers 22 each have a surface in contact with the first electrode 21, and the surfaces of the first contact layers 22 in the pixels P are flush with one another. In other words, of the plurality of first contact layers 22, the surfaces in contact with the first electrodes 21 are flush with one another.

The photoelectric conversion layer 23 between the first electrode 21 and the second electrode 25 absorbs light of a predetermined wavelength to generate signal charges, and includes an inorganic semiconductor material such as a Group III-V semiconductor. Examples of the inorganic semiconductor material included in the photoelectric conversion layer 23 include Ge (germanium), InGaAs (indium gallium arsenide), Ex.InGaAs, InAsSb (indium arsenide antimonide), InAs (indium arsenide), InSb (indium antimonide), and HgCdTe (mercury cadmium tellurium). One photoelectric conversion layer 23 is disposed for a corresponding one of the pixels P, and the photoelectric conversion layers 23 in adjacent ones of the pixels P are electrically separated from each other by the insulating film 13. Specifically, the pixel P1 is provided with a photoelectric conversion layer 23A, the pixel P2 is provided with a photoelectric conversion layer 23B, the pixel P3 is provided with a photoelectric conversion layer 23C, the pixel P4 is provided with a photoelectric conversion layer 23D, and the pixel P5 is provided with a photoelectric conversion layer 23E. In other words, the photoelectric conversion layers 23A to 23E are disposed at respective positions that are different in a planar view. In the present embodiment, the inorganic semiconductor material included in the photoelectric conversion layer 23A (or the photoelectric conversion layers 23B to 23D) is different from the inorganic semiconductor material included in the photoelectric conversion layer 23E. This makes it possible to perform photoelectric conversion in a wide wavelength band, as described in detail later. Here, the photoelectric conversion layer 23E corresponds to a specific example of a first photoelectric conversion layer of the present technology, and the photoelectric conversion layer 23A (or the photoelectric conversion layers 239 to 23D) corresponds to a specific example of a second photoelectric conversion layer of the present technology.

The photoelectric conversion layers 23A, 23B, and 23C mainly perform photoelectric conversion of light of wavelengths in the visible region. Light in a blue wavelength region (e.g., a wavelength in a range of 500 nm or less) is absorbed in the photoelectric conversion layer 23A, light in a green wavelength region (e.g., a wavelength in a range of 500 nm to 600 nm) is absorbed in the photoelectric conversion layer 239, and light in a red wavelength region (e.g., a wavelength in a range of 600 nm to 800 nm) is absorbed in the photoelectric conversion layer 23C, and signal charges are thereby generated. These photoelectric conversion layers 23A to 23C include, for example, a Group III-V semiconductor of an i-type. Examples of the Group III-V semiconductor used for the photoelectric conversion layers 23A to 23C include InGaAs (indium gallium arsenide). For example, the photoelectric conversion layers 23A, 23B, and 23C have respective thicknesses different from one another. For example, the thickness of the photoelectric conversion layer 23A is the smallest, and the thicknesses of the photoelectric conversion layer 23B and the photoelectric conversion layer 23C are larger in this order. For example, the thickness of the photoelectric conversion layer 23A is 500 nm or less, the thickness of the photoelectric conversion layer 23B is 700 nm or less, and the thickness of the photoelectric conversion layer 23C is 800 nm or less.

The photoelectric conversion layer 23D mainly performs photoelectric conversion of light of a wavelength in a short infrared region (e.g., a wavelength in a range of 1 μm to 10 μm). This photoelectric conversion layer 23D includes, for example, a Group III-V semiconductor of the i-type, and includes, for example, InGaAs (indium gallium arsenide). The photoelectric conversion layer 23D is, for example, thicker than the photoelectric conversion layers 23A to 23C, and the photoelectric conversion layer 23D has a thickness of, for example, 1 μm to 10 μm.

The photoelectric conversion layer 23E mainly performs photoelectric conversion of light of a wavelength in an intermediate infrared region (e.g., a wavelength in a range of 3 μm to 10 μm). This photoelectric conversion layer 23E includes, a Group III-V semiconductor of the i-type that is different from those of the photoelectric conversion layers 23A to 23D. Specifically, it is possible to use InAsSb (indium arsenide antimonide), InSb (indium antimonide), or the like for the photoelectric conversion layer 23E. In this way, in the pixel P (the pixel P5), the inorganic semiconductor material different from those of the photoelectric conversion layers 23 in the other pixels P is used, which makes it possible to photoelectrically convert light in a longer wavelength region. It is therefore possible to achieve high photoelectric conversion efficiency in a wide wavelength band. For example, the thickness of the photoelectric conversion layer 23E is different from the thicknesses of the photoelectric conversion layers 23A to 23C, and is, for example, 3 μm to 10 μm.

The second contact layer 24 is provided between the photoelectric conversion layer 23 and the second electrode 25, and is in contact with the photoelectric conversion layer 23 and the second electrode 25. One second contact layer 24 is disposed for a corresponding one of the pixels P, and the second contact layers 24 in adjacent ones of the pixels P are electrically separated from each other by the insulating film 13. The second contact layer 24 serves as a region where electric charges discharged from the second electrode 25 move, and includes, for example, a compound semiconductor including an n-type impurity. For example, it possible to use InP (indium phosphide) including an n-type impurity such as Si (silicon), for the second contact layer 24.

The second electrode 25 is provided as, for example, an electrode that is common to the respective pixels P on the second contact layer 24 (light incident side) to be in contact with the second contact layer 24. The second electrode 25 discharges electric charges that are not used as signal charges of the electric charges generated in the photoelectric conversion layer 23 (cathode). For example, in a case where holes are read from the first electrode 21 as signal charges, it is possible to discharge, for example, electrons through this second electrode 25. The second electrode 25 includes, for example, a conductive film that allows incident light such as an infrared ray to pass therethrough. It is possible to use, for example, ITO (Indium Tin Oxide), ITiO (In₂O₃—TiO₂), or the like for the second electrode 25.

The protective film 12 is provided to cover one surface (a surface on the light incident side) of the ROIC substrate 11. The protective film 12 includes, for example, an inorganic insulating material. Examples of this inorganic insulating material include silicon nitride (SiN), aluminum oxide (Al₂O₃), silicon oxide (SiO₂), hafnium oxide (HfO₂), etc, The protective film 12 may have a stacked structure including a plurality of films. The through electrode 12E provided in the protective film 12 couples a wiring line of the ROIC substrate 11 to the first electrode 21, and is provided for each of the pixels P. The through electrode 12E includes, for example, copper,

For example, the insulating film 13 covers a side surface of the first contact layer 22, a side surface of the photoelectric conversion layer 23, and a side surface of the second contact layer 24, in each of the pixels P. This insulating film 13 separates the photoelectric conversion layers 23 adjacent to each other for each of the pixels P, and a region between the photoelectric conversion layers 23 adjacent to each other is filled with the insulating film 13. The insulating film 13 includes, for example, an oxide such as silicon oxide (SiOₓ) or aluminum oxide Al₂O₃), The insulating film 13 may include a stacked structure including a plurality of films. The insulating film 13 may include, for example, a silicon (Si)-based insulating material such as silicon oxynitride (SiON), carbon-containing silicon oxide (SiOC), silicon nitride (SiN), and silicon carbide (SiC).

The passivation film 14 covers the second electrode 25, and is provided between the second electrode 25 and the color filter layer 15. This passivation film 14 may have an antireflection function. It possible to use, for example, silicon nitride (SiN), aluminum oxide (Al₂O₃), silicon oxide (SiO₂). tantalum oxide (Ta₂O₃), etc., for the passivation film 14.

The color filter layer 15 is provided on the passivation film 14 (on light incident surface side of the passivation film 14). The color filter layer 15 includes, for example, a blue filter in the pixel P1, a green filter in the pixel P2, and a red filter in the pixel P3. For example, light of wavelengths in the infrared region is photoelectrically converted in the pixels P4 and P5 and thus, the color filter layer 15 may include a visible-light cut filter in the pixels P4 and P5.

The light-receiving device 1 may include, on the color filter layer 15, an on-chip lens (for example, an on-chip lens 17 in FIG. 8 described later) to condense incident light toward the photoelectric conversion layer 23.

### [Method of Manufacturing Light Receiving Device 1]

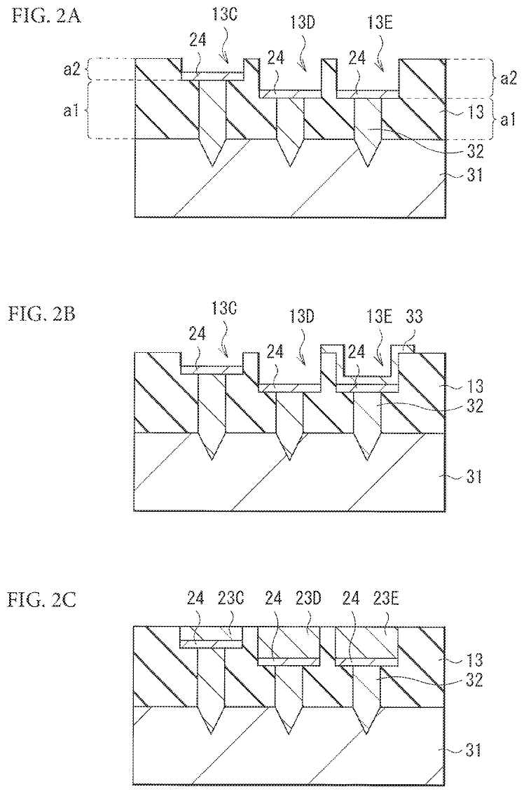

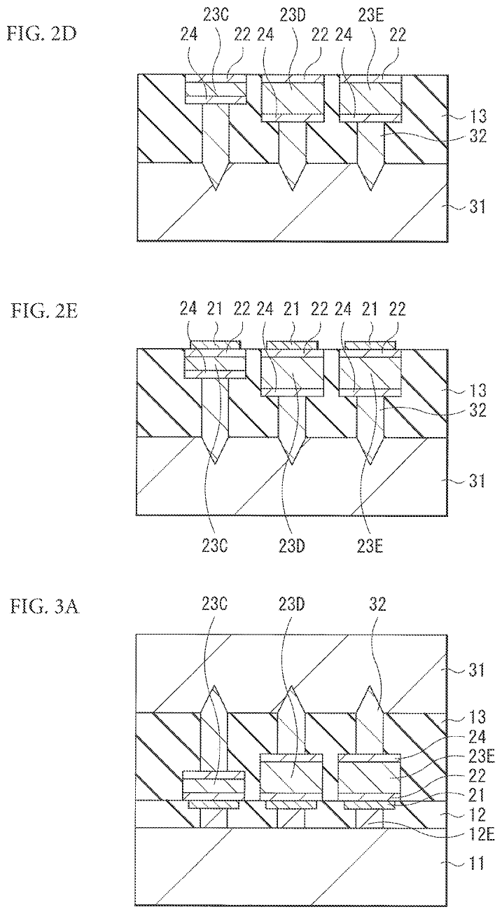

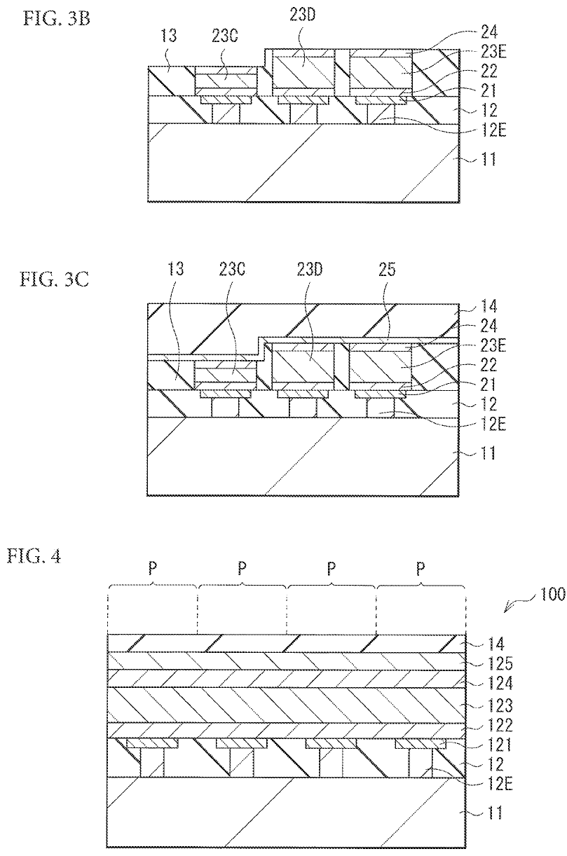

It is possible to manufacture the light-receiving device 1 as follows, for example. FIGS. 2A to 3C illustrate manufacturing processes of the light-receiving device 1 in process order. FIGS. 2A to 3C each depict a region corresponding to the pixels P3 to P5.

First, a substrate 31 including, for example, silicon (Si) is prepared, and the insulating film 13 including, for example, silicon oxide (SiO₂,) or silicon nitride (SiN) is formed on this substrate 31.

Next, as illustrated in FIG. 2A, an opening (openings 13C to 13E corresponding to the pixels P3 to P5) is formed in a region corresponding to each of the pixels P of the formed insulating film 13, and the second contact layer 24 is formed in this opening. Specifically, the following is performed. First, the insulating film 13 is patterned through using, for example, photolithography and dry etching to form the openings 13C to 13E. The openings 13C to 13E are formed for the respective pixels P, and each include portions a1 and a2 having respective open widths different from each other. The portion a2 is an opening portion where the photoelectric conversion layer 23 is formed in a later process, and has a depth adjusted for each of the pixels P in accordance with the thickness of the formed photoelectric conversion layer 23. The thickness of the photoelectric conversion layer 23 is thus adjusted by the depth of the portion a2, which makes it possible to manufacture the light-receiving device 1 easily. The portion a1 has a higher aspect ratio than the portion a2, and is formed as a trench or an aperture within the portion a2. The aspect ratio of the portion a1 is, for example, 1.5 or more. The portion a1 penetrates the insulating film 13 from the portion a2, and is also provided in a portion (a portion on side of the insulating film 13) of the substrate 31.

Of the portion a1, an exposed surface of a substrate 51 is subjected to, for example, alkali anisotropic etching. In this etching, for example, crystal plane orientation dependence of the silicon substrate (the substrate 31) is strong, and an etching rate in a (111) plane direction is extremely low. For this reason, as for an etching processing surface, etching stops at a (111) plane, and a plurality of (111) planes is formed.

After the etching process is performed, a buffer layer 32 including InP is formed from the plurality of (111) planes of the substrate 31 to the portion a1 of the insulating film 13 with use of a MOCVD (Metal Organic Chemical Vapor Deposition) method or a MBE (Molecular Beam Epitaxy) method. Inr this way, the buffer layer 32 is epitaxially grown from the plurality of (111) planes inclined with respect to the surface of the substrate 31, which makes it possible to reduce defect density of the buffer layer 32. One reason for this is that growth of stacking fault starts from an interface between the inclined (111) plane and the buffer layer 32 in a film formation direction, but at this moment, this stacking fault hits a wall of the insulating film 13 and thereby the growth stops. After the buffer layer 32 is formed in the portion a1, for example, InP is epitaxially grown in the portion a2 to form the second contact layer 24 (FIG. 2A),

Subsequently, the photoelectric conversion layer 23 is formed in each of the openings (the openings 13C to 13E) (FIGS. 2B and 2C). The photoelectric conversion layer 23 is formed with use of, for example, a hard mask 33. Specifically, the photoelectric conversion layers 23C to 23E are formed in the openings 13C to 13E as follows. First, in a state where the opening 13E is covered with the hard mask 33, the photoelectric conversion layers 23C and 23D including, for example, InGaAs (indium gallium arsenide) are formed in the openings 13C and 13D by epitaxial growth. Thereafter, in a state where the openings 13C and 13D are covered with the hard mask 33, the photoelectric conversion layer 23E including, for example, InAsSb (indium arsenide antimonide) or InSb (indium antimonide) is formed in the opening 13E by epitaxial growth.

After the photoelectric conversion layer 23 is formed, for example, InP is epitaxially grown on the photoelectric conversion layer 23 to form the first contact layer 22, as illustrated in FIG: 2D. Subsequently, a surface of the first contact layer 22 is flattened by, for example, CMP (Chemical Mechanical Polishing).

Next, on the flattened surface of the first contact layer 22, a film including the constituent material of the first electrode 21 is formed, and this film is patterned with use of photolithography and etching. The first electrode 21 is thereby formed (FIG. 2E).

Subsequently, the protective film 12 and the through electrode 12E are formed. Specifically, after the protective film 12 is formed on the first electrode 21 and on the insulating film 13, a through-hole is formed in a region, corresponding to a central portion of the first electrode 21, of this protective film 12 with use of, for example, photolithography and dry etching. Thereafter, the through electrode 12E including, for example, copper is formed in this through-hole.

Next, as illustrated in FIG. 3A, this through electrode 12E is bonded to an electrode of the ROIC substrate 11. For example, such bonding is performed by Cu—Cu bonding. Subsequently, the substrate 31 is thinned by, for example, a grinder, and the thinned substrate 31 and the buffer layer 32 are removed by, for example, etching to expose a surface of the second contact layer 24 (FIG. 3B).

Finally, as illustrated in FIG. 3C, the second electrode 25, the passivation film 14, and the color filter layer 15 are formed in this order, thereby completing the light-receiving device 1 illustrated in FIG 1.

### [Operation of Light Receiving Device 1]

In the light-receiving device 1, in a case where light (e.g., light of wavelengths in the visible region and the infrared region) is incident on the photoelectric conversion layer 23 through the color filter layer 15, the passivation film 14, the second electrode 25, and the second contact layer 24, this light is absorbed in the photoelectric conversion layer 23. A pair of a hole (a positive hole) and an electron is thereby generated in the photoelectric conversion layer 23 (photoelectric conversion is performed). At this moment, in a case where, for example, a predetermined voltage is applied to the first electrode 21, a potential gradient occurs in the photoelectric conversion layer 23, and one (e.g., the hole) of the generated electric charges moves to the first contact layer 22 as a signal charge, and is collected from the first contact layer 22 to the first electrode 21. This signal charge is read by the ROIC substrate 11.

### [Workings and Effects of Light Receiving Device 1]

In the light-receiving device 1 of the present embodiment, the photoelectric conversion layers 23A to 23D of the pixels P1 to P4 and the photoelectric conversion layer 23E of the pixel P5 include the inorganic semiconductor materials different from each other. In addition, it is possible to adjust the thicknesses of the respective photoelectric conversion layers 23A to 23D to be different from one another. This makes it easy to set a photoelectrically convertible wavelength band in each of the photoelectric conversion layers 23A to 23E (the pixels P1 to P5). For example, it is possible to provide such a configuration in which photoelectric conversion is performed for the light in the blue wavelength region in the photoelectric conversion layer 23A (the pixel P1), the light in the green wavelength region in the photoelectric conversion layer 23B (the pixel P2), the light in the red wavelength region in the photoelectric conversion layer 23C (the pixel P3), the light of the wavelength in the short infrared region in the photoelectric conversion layer 23D (the pixel P4), and the light of the wavelength in the intermediate infrared region in the photoelectric conversion layer 23E (the pixel P5). This is described below.

FIG. 4 illustrates a cross-sectional configuration of a light-receiving device (a light-receiving device 100) according to a comparative example. In this light-receiving device 100, adjacent ones of the pixels P are not separated from each other by an insulating film. and a first contact layer 122, a photoelectric conversion layer 123, a second contact layer 124, and a second electrode 125 are provided common to all the pixels P. A first electrode 121 is separated for each of the pixels P.

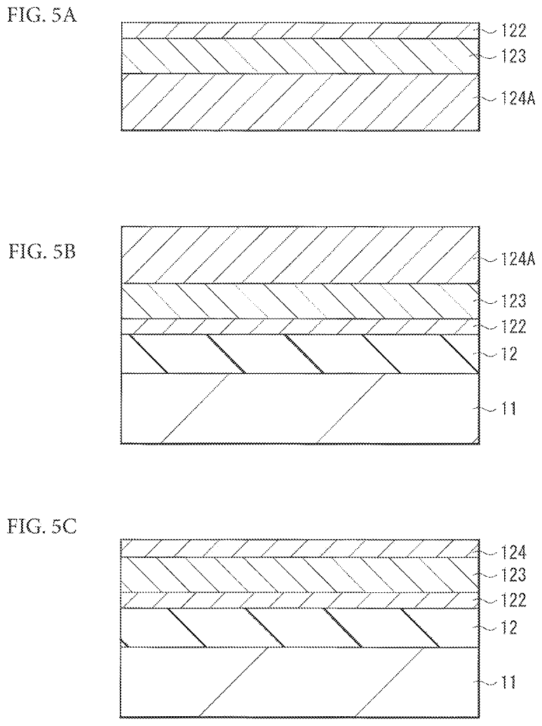

FIGS. 5A to 5C illustrate manufacturing processes of this light-receiving device 100. For the light-receiving device 100, first, the photoelectric conversion layer 123 and the first contact layer 122 are formed on a substrate 124A by, for example, epitaxial growth (FIG. 5A) and then, the protective film 12 and a through electrode (not illustrated) are formed. Next, this through electrode and the electrode of the ROIC substrate 11 are bonded to each other by, for example, Cu—Cu bonding (FIG. 5B), Thereafter, for example, the substrate 124A is thinned to form the second contact laser 124 (FIG. 5C). Finally, for example, the second electrode 125, a passivation film, and a color filter layer are formed, thereby forming the light-receiving device 100.

In the light-receiving device 100 thus formed, it is difficult to vary a constituent material of the photoelectric conversion layer 123, or to vary a thickness of the photoelectric conversion layer 123, from one pixel P to another. For this reason, in the light-receiving device 100, light in the same wavelength region is photoelectrically converted in all the pixels P, and it is not possible to perform photoelectric conversion selectively on light in a wavelength region different for each of the pixels P.

In contrast, in the light-receiving device 1, the photoelectric conversion layers 23A to 23E of the constituent materials different from one another, or of the different thicknesses, are provided and it is thus possible to perform photoelectric conversion selectively on light in a wavelength region different for each of the pixels P. For example, photoelectric conversion is performed selectively on the light of the wavelength in the visible region in each of the pixels P1 to P3, the light of the wavelength in the short infrared region in the pixel P4, and the light of the wavelength in the intermediate infrared region in the pixel P5. It is possible to form such a light-receiving device 1 easily, through forming the photoelectric conversion layer 23 in the opening (e.g., the openings 13C to 13E in FIG. 24) provided in the insulating film 13 for each of the pixels P.

As described above, in the light-receiving device 1 of the present embodiment, the photoelectric conversion layers 23A to 23D and the photoelectric conversion layer 23E include the inorganic semiconductor materials different from each other, which makes it possible to shift the photoelectrically convertible wavelengths of the photoelectric conversion layers 23A to 23D and the photoelectric conversion layer 23E. In addition, the thicknesses are different among the photoelectric conversion layers 23A to 23D, and it is thus possible to shift the photoelectrically convertible wavelengths. It is therefore possible to perform photoelectric conversion in a wide wavelength band.

Modification examples and application examples of the foregoing embodiment are described below, and the same components as those of the foregoing embodiment are denoted by the same reference numerals, and the descriptions thereof are omitted where appropriate.

### MODIFICATION EXAMPLE 1

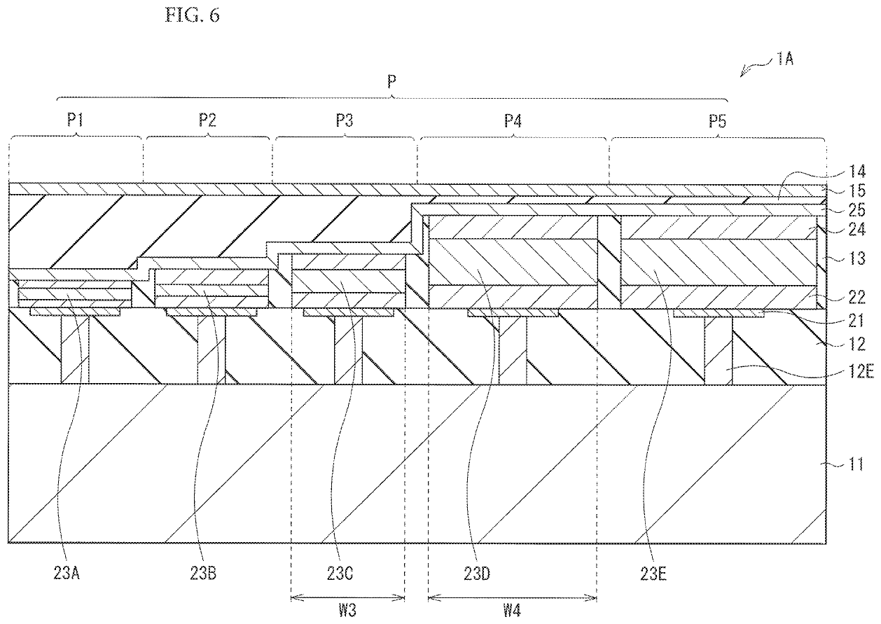

FIG. 6 illustrates a cross-sectional configuration of a light-receiving device (a light-receiving device 1A) according to a modification example 1 of the foregoing embodiment. As in the light-receiving device 1A, the photoelectric conversion layers 23 having different widths (widths W3 and W4) may be provided. Except for this point, the light-receiving device 14 has a configuration and effects similar to those of the light-receiving device 1.

For example, in the light-receiving deuce 1A, the width W4 of the photoelectric conversion layer 23D is larger than the width W3 of the photoelectric conversion layer 23C. For example, the width of each of the photoelectric conversion layers 23A and 23B is substantially the same as the width W3, and the width of the photoelectric conversion layer 23E is larger than the width W4. For example, the photoelectric conversion layer 23C and the photoelectric conversion layer 23D have different sizes in a planar view, and also have different lengths (sizes in a direction orthogonal to the widths W3 and W4). Only either the widths W3 and W4 or the lengths may be different between the photoelectric conversion layer 23C and the photoelectric conversion layer 23D.

### MODIFICATION EXAMPLE 2

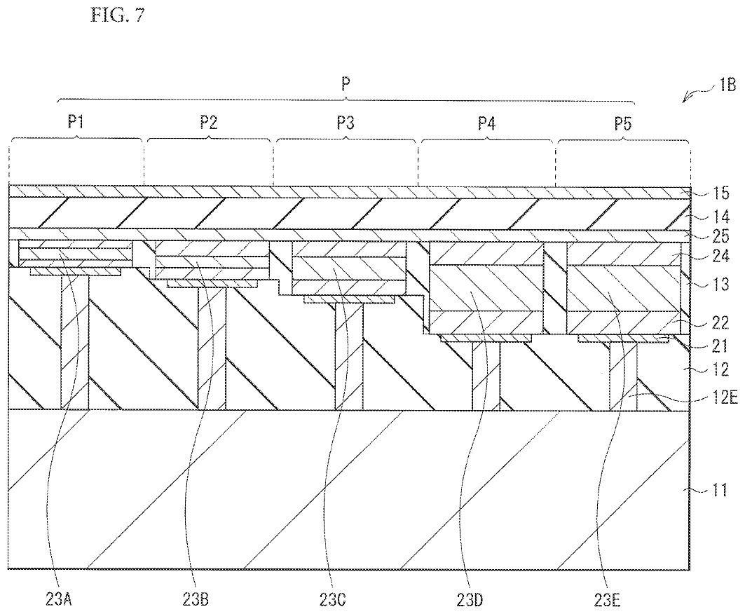

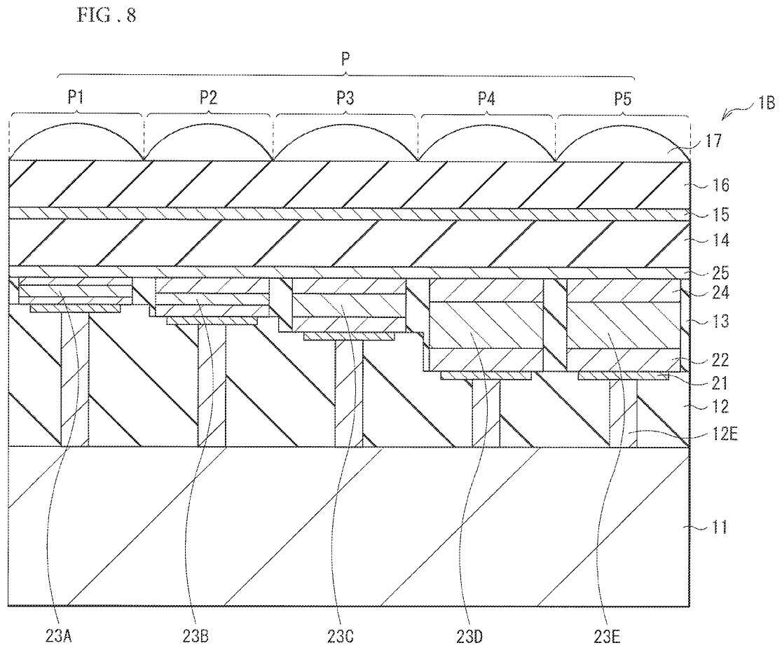

FIG. 7 illustrates a cross-sectional configuration of a light-receiving device (a light-receiving device 1B) according to a modification example 2. In the foregoing embodiment, the case where the surface on side of the ROIC substrate 11 (specifically, the surface, in contact with the first electrode 21, of the first contact layer 22) is flat is described as an example, but the surface on the light incident side may be flat. Specifically, as in the light-receiving device 1B, the second contact layers 24 may each have a surface in contact with the second electrode 25 and the surfaces of the second contact layers 24 in the pixels P may be flush with one another. In other words, in the light-receiving device 1B, of the plurality of second contact layers 24, the surfaces in contact with the second electrode 25 are flush with one another. Except for this point, the light-receiving device 13 has a configuration and effects similar to those of the light-receiving device 1.

As illustrated in FIG. 8, the light-receiving device 1B may include an on-chip lens (the on-chip lens 17). The on-chip lens 17 is provided, for example, on the color filter layer 15, with a passivation film 16 interposed therebetween. In this way, in the light-receiving device 1B in which the light incident surface is flat, a focus design of the on-chip lens 17 is easy, and it is possible to form the on-chip lens 17 easily.

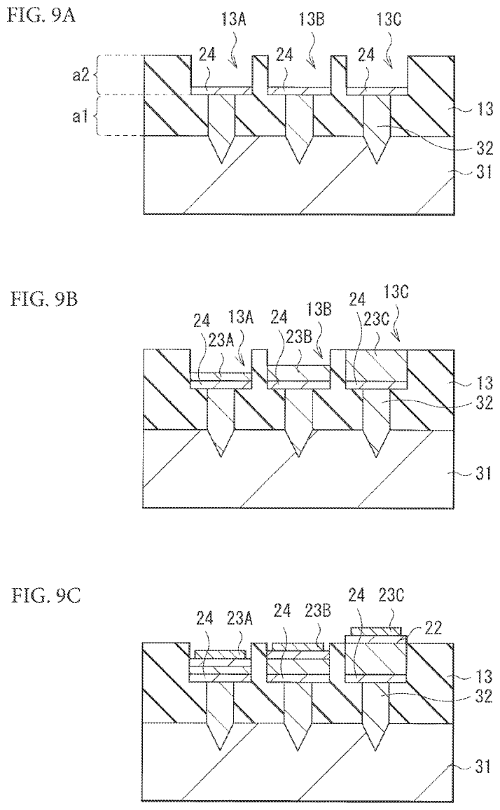

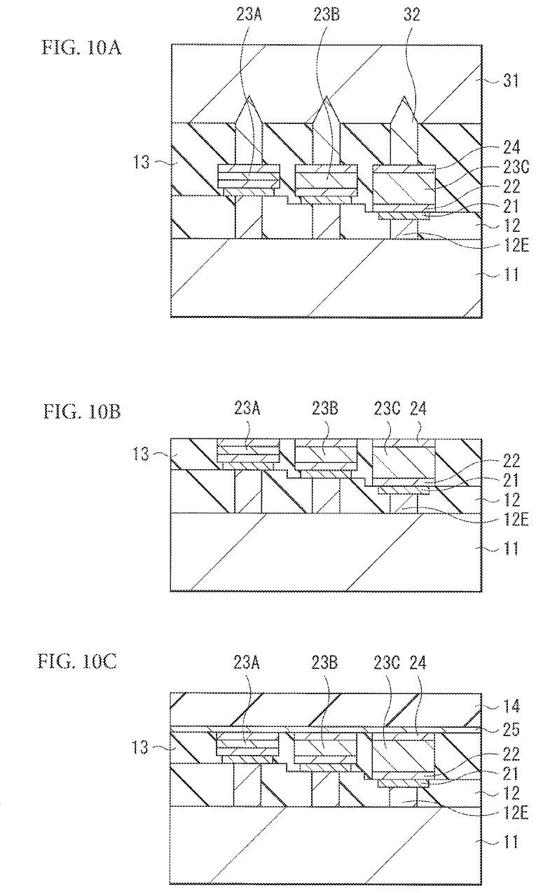

It is possible to manufacture the light-receiving device 1B as follows, for example. FIGS. 9A to IOC illustrate manufacturing processes of the light-receiving device 1B in process order. FIGS. 9A to 10C each depict a region corresponding to the pixels P1 to P3.

First, in a manner similar to the manner described in the foregoing embodiment, an opening (openings 134 to 13C corresponding to the pixels P1 to P3) is formed in the region, corresponding to each of the pixels P, of the insulating film 13, and the second contact layer 24 is formed in this opening (FIG. 9A). At this moment, the depth of the portion a2 are the same in the pixels P, and thereby, of the second contact layers 24, the surfaces in contact with the second electrode 25 in the pixels P are flush with one another.

Next, the photoelectric conversion layer 23 is formed in each of the openings (the openings 13A to 13C) (FIG: 9B). For example, the photoelectric conversion layers 234 to 23C are formed through epitaxially growing InGaAs (indium gallium arsenide) and thereafter adjusting thicknesses of InGaAs for the respective pixels P by etching.

After the photoelectric conversion layer 23 is formed, the first contact layer 22 and the first electrode 21 are formed in this order on the photoelectric conversion layer 23, as illustrated in FIG. 9C. Subsequently, the protective film 12 and the through electrode 12E are formed and then, this through electrode 12E is bonded to the electrode of the ROIC substrate 11, as illustrated in FIG. 104.

Thereafter, the substrate 31 is thinned, and the substrate 31 and the buffer layer 32 are removed by, for example, etching to expose the surface of the second contact layer 24 (FIG. 10B).

Finally, as illustrated in FIG. 10C, the second electrode 25, the passivation film 14, and the color filter layer 15 are formed in this order, thereby completing the light-receiving device 1B illustrated in FIG. 7.

As in the present modification example, the surface on the light incident surface side may be flat among the pixels P, and even in this case, it is possible to obtain effects similar to the effects of the foregoing embodiment. In addition, the focus design of the on-chip lens 17 is easy.

### MODIFICATION EXAMPLE 3

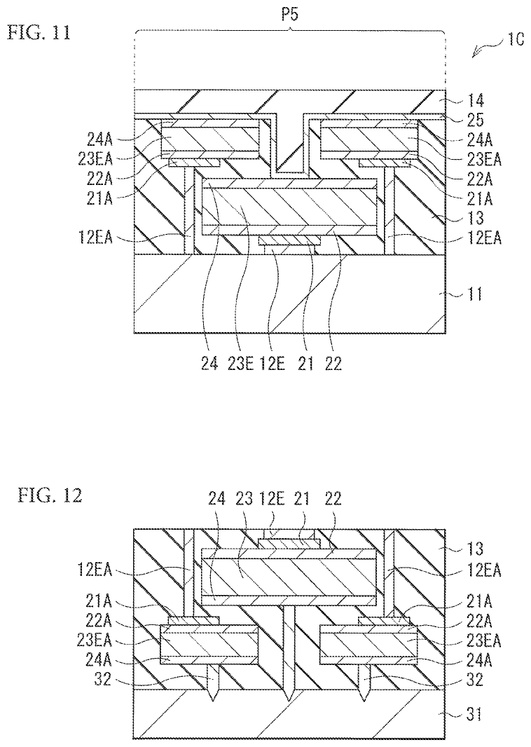

FIG. 11 illustrates a cross-sectional configuration of the pixel PS in a light-receiving device (a light-receiving device 1C) according to a modification example 3. As in the present modification example, another photoelectric conversion layer (a photoelectric conversion layer 23EA) may be stacked in a thickness direction of the photoelectric conversion layer 23E. In such a light-receiving device 1C, light dispersion in a longitudinal direction is possible. Except for this point, the light-receiving device 1C has a configuration and effects similar to those of the light-receiving device 1.

The photoelectric conversion layer 23E4 (a third photoelectric conversion layer) is stacked in the thickness direction of the photoelectric conversion layer 23E, and is provided at a position where a portion of the photoelectric conversion layer 23EA overlaps the photoelectric conversion layer 23E in a planar view. The photoelectric conversion layer 23EA includes an inorganic semiconductor material different from the material of the photoelectric conversion layer 23E. For example, the photoelectric conversion layer 23EA mainly performs photoelectric conversion of light of a wavelength in the short infrared region, and includes InGaAs (indium gallium arsenide). The pixel P5 is provided, for example, with two photoelectric conversion layers 23EA, and these photoelectric conversion layers 23E4 are disposed at the same position in the thickness direction. The pixel P5 may be provided with one photoelectric conversion layer 23EA, or may be provided with three or more photoelectric conversion lavers 23EA.

A surface, opposed to the ROIC substrate 11, of the photoelectric conversion layer 23EA is provided with a first electrode 21A, and the first electrode 21A is coupled to the ROIC substrate 11 through a through electrode 12EA in the insulating film 13. A first contact layer 22A is provided between the photoelectric conversion layer 23E4 and the first electrode 21A. A second contact layer 24A and the second electrode 25 are stacked in this order on a light incident surface of the photoelectric conversion layer 23EA.

FIG. 12 illustrates one process in manufacturing the light-receiving device 1C. It is possible to form the light-receiving device 1C in a manner similar to the manner described in the foregoing embodiment.

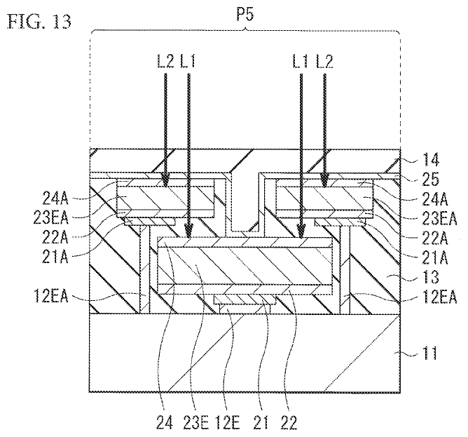

In the light-receiving device 1C, as illustrated in FIG. 13, for example, in the one pixel P5, light L1 of a wavelength in the intermediate infrared region is photoelectrically converted by the photoelectric conversion layer 23E, and, for example, light L2 of a wavelength in the short infrared region is photoelectrically converted by the photoelectric conversion layer 23EA.

As in the present modification example, a plurality of photoelectric conversion layers (e.g., the photoelectric conversion layer 23E and the photoelectric conversion layer 23EA) may be provided in a stacking direction in one pixel P. Even in this case, it is possible to obtain effects similar to those of the above-described first embodiment. In addition, because light dispersion in the longitudinal direction is possible within the one pixel P, which makes it easy to make the pixel P finer

FIG. 11 illustrates the case where the photoelectric conversion layer 23EA is provided in the pixel P5, but the photoelectric conversion layer 23EA may be provided in the pixel P5 as well as any other pixel P (e.g., the pixels P1 to P4). Alternatively, the photoelectric conversion layer 23EA may be provided in another pixels P without being provided in the pixel P5.

### APPLICATION EXAMPLE 1

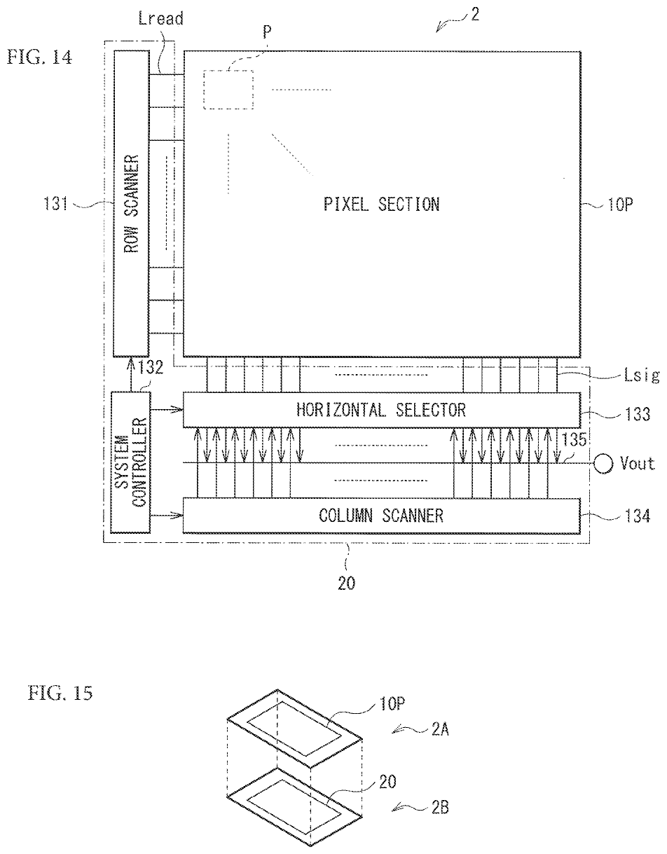

FIG. 14 illustrates a functional configuration of an imaging device 2 using an device structure of the light-receiving device 1 (or the light-receiving devices 1A to 1C, hereinafter collectively referred to as the light-receiving device 1) described in the foregoing embodiment, etc. Examples of the imaging device 2 include an infrared image sensor, and the imaging device 2 includes, for example, a pixel section 131 including the light-receiving device 1, and a circuit section 20 that drives this pixel section 10P. The circuit section 20 includes, for example, a row scanner 131, a horizontal selector 133, a column scanner 134, and a system controller 132.

The pixel section 10P includes, for example, the plurality of pixels P (the light-receiving devices 1) arranged two-dimensionally in a matrix. For example, the pixels P are wired with pixel drive lines Lread (specifically, row selection lines and reset control lines) for respective pixel rows, and wired with vertical signal lines Lsig for respective pixel columns. The pixel drive lines Lread transmit drive signals for signal reading from the pixels P. The pixel drive lines each have one end coupled to a corresponding one of output terminals, corresponding to the respective rows, of the row scanner 131.

The row scanner 131 serves as a pixel driver that includes a shift register, an address decoder, etc., and drives each of the pixels P of the pixel section 10 on a row-by-row basis, for example. A signal outputted from each of the pixels P of a pixel row selected and scanned by the row scanner 131 is supplied to the horizontal selector 133 through each of the vertical signal lines Lsig. The horizontal selector 133 includes an amplifier, a horizontal selection switch, etc. provided for each of the vertical signal lines Lsig.

The column scanner 134 includes a shift register, an address decoder, etc., and sequentially drives respective horizontal selection switches of the horizontal selector 133 while scanning the horizontal selection switches. Such selective scanning by the column scanner 134 causes signals of the respective pixels transmitted through the respective vertical signal lines Lsig to be outputted in sequence to a horizontal signal line 135 and thereafter inputted to an unillustrated signal processor, etc. through the horizontal signal line 135.

In this imaging device 2, as illustrated in FIG. 15, for example, a substrate 2A including the pixel section 10P and a substrate 2B (e.g., the ROIC substrate 11 in FIG. 1) including the circuit section 20 are stacked. However, such a configuration is not limitative, and the circuit section 20 may be formed on the same substrate as the substrate of the pixel section 10P, or may be disposed in an external control IC. Further, the circuit section 20 may be formed in another substrate coupled by a cable, etc.

The system controller 132 receives a clock provided from outside, data to command an operation mode, etc., and also outputs data such as internal information of the imaging device 2. The system controller 132 further includes a timing generator that generates various timing signals, and performs driving control of the row scanner 131, the horizontal selector 133, the column scanner 134, etc., on the basis of the various timing signals generated by this timing generator,

### APPLICATION EXAMPLE 2

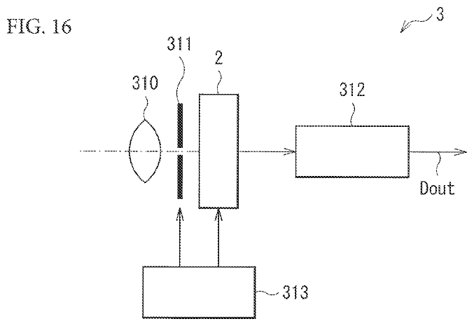

The above-described imaging device 2 is applicable to various types of electronic apparatuses such as a camera that enables imaging of, for example, an infrared region. FIG. 16 illustrates a schematic configuration of an electronic apparatus 3 (a camera), as an example. Examples of the electronic apparatus 3 include a camera that enables of shooting of a still image or a moving image, and the electronic apparatus 3 includes the imaging device 2, an optical system (an optical lens) 310, a shutter apparatus 311, a driver 313 that drives the imaging device 2 and the shutter apparatus 311, and a signal processor 312.

The optical system 310 guides image light (incident light) from a subject to the imaging device 2. This optical system 310 may include a plurality of optical lenses. The shutter apparatus 311 controls a period in which the imaging device 2 is irradiated with the light and a period in which the light is blocked. The driver 313 controls a transfer operation of the imaging device 2 and a shutter operation of the shutter apparatus 311, The signal processor 312 performs various kinds of signal processing on a signal outputted from the imaging device 2. An image signal Dout having been subjected to the signal processing is stored in a storage medium such as a memory or outputted to a monitor, etc.

Further, the light-receiving device 1 described in the present embodiment, etc. is also applicable to the following electronic apparatuses (a capsule endoscope and a mobile body such as a vehicle).

### FURTHER APPLICATION EXAMPLE 1 (ENDOSCOPIC SURGERY SYSTEM)

The technology according to the present disclosure (the present technology) is applicable to various products. For example, the technology according to the present disclosure may be applied to an endoscopic surgery system.

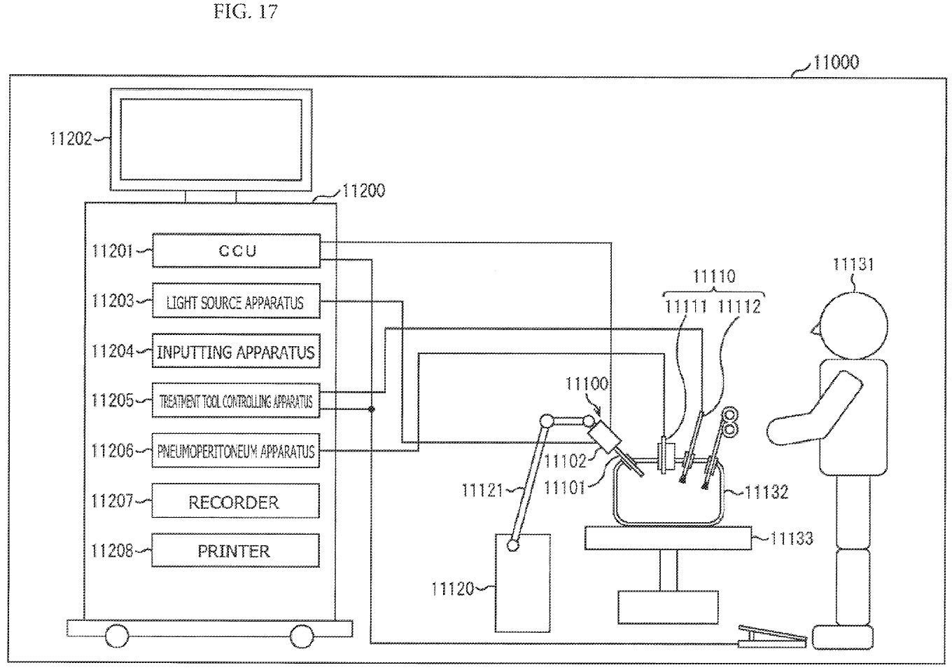

FIG. 17 is a view depicting an example of a schematic configuration of an endoscopic surgery system to which the technology according to an embodiment of the present disclosure (present technology) can be applied.

In FIG. 17, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. it is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example. an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

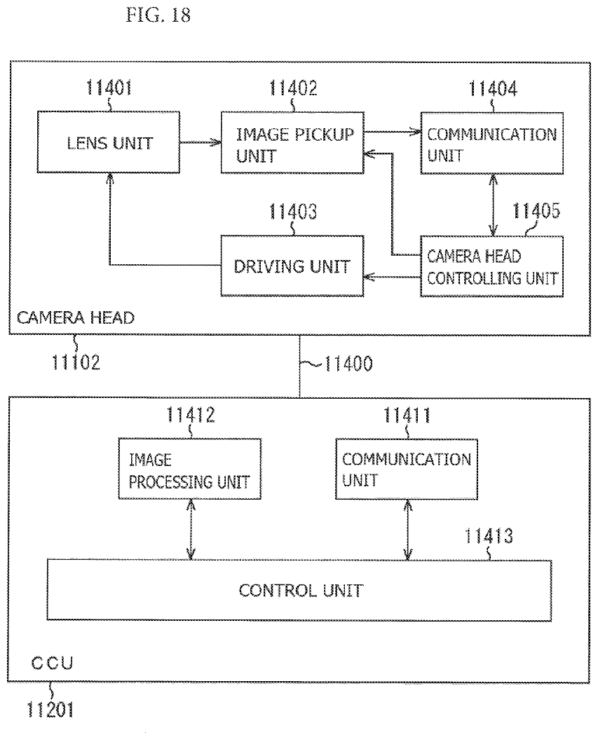

FIG. 18 is a block diagram depicting an example of a functional configuration of the camera head 11102 and the CCU 11201 depicted in FIG. 17.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image, The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information o and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404,

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an Image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the foregoing, the description has been given of one example of the endoscopic surgery system to which the technology according to the present disclosure is applicable. The technology according to the present disclosure may be applied to the image pickup unit 11402 among the components of the configuration described above. Applying the technology according to the present disclosure to the image pickup unit 11402 makes it possible to obtain a clearer image of the surgical region. Hence, it is possible for the surgeon to confirm the surgical region with certainty.

Note that the description has been given above of the endoscopic surgery system as one example. The technology according to the present disclosure may be applied to any medical system besides the endoscopic surgery system, such as a micrographic surgery system.

### FURTHER APPLICATION EXAMPLE 2 (MOBILE BODY)

The technology according to the present disclosure is applicable to various products, For example, the technology according to the present disclosure may be achieved in the form of an apparatus to be mounted to a mobile body of any kind such as an automobile, an electric vehicle, a hybrid electric vehicle, a motorcycle, a bicycle, a personal mobility, an airplane, a drone, a vessel, and a robot.

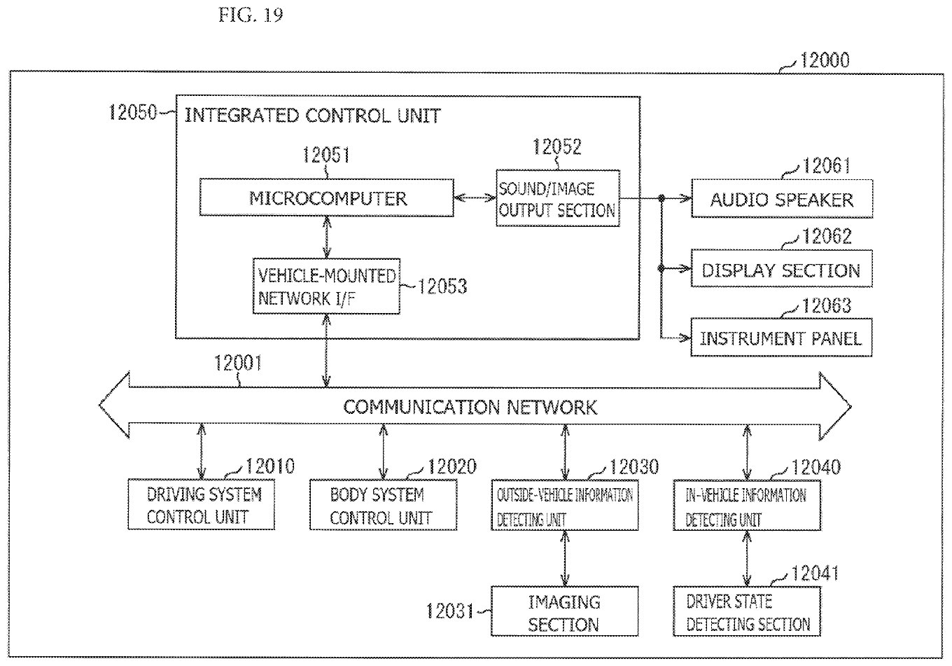

FIG. 19 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 19, the vehicle control system 12000 includes a driving system control unit 12010, a body system control unit 12020, an outside-vehicle information detecting unit 12030, an in-vehicle information detecting unit 12040, and an integrated control unit 12050. in addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 19, an audio speaker 12061, a display section 12062, and an instrument panel 12063 are illustrated as the output device. The display section 12062 may, for example, include at least one of an on-board display and a head-up display.

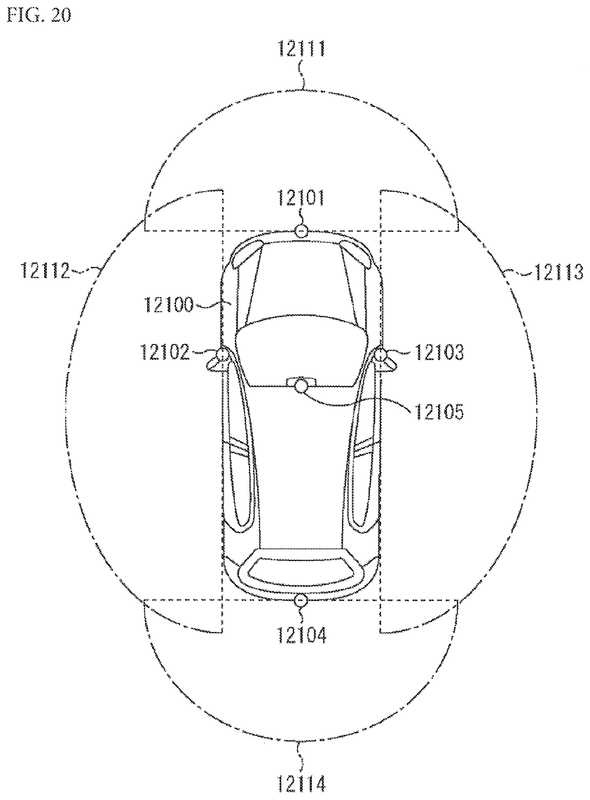

FIG. 20 is a diagram depicting an example of the installation position of the imaging section 12031.

In FIG. 20, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like,

Incidentally, FIG. 20 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract he classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a. procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the foregoing, the description has been given of one example of the vehicle control system, to which the technology according to the present disclosure is applicable. The technology according to the present disclosure may be applied to, for example, the imaging section 12031 among components of the configuration described above. Applying the technology according to the present disclosure to the imaging section 12031 makes it possible to obtain a captured image that is easier to see. Hence, it is possible to reduce fatigue of the driver

Furthermore, the light-receiving device 1 described in the present embodiment, etc is applicable to electronic apparatuses such as a surveillance camera, a biometric authentication system, and a thermograph. Examples of the surveillance camera include a camera of a night vision system (night vision). Applying the light-receiving device 1 to the surveillance camera makes it possible to recognize a pedestrian and an animal at night from a distance. Further, influences of a headlight and weather are reduced by application of the light-receiving device 1 to a vehicle-mounted camera. For example, it is possible to capture an image by shooting without influences of smoke, fog, etc. Furthermore, it is also possible to recognize shape of an object. Moreover, in the thermography, it is possible to perform non-contact temperature measurement. The thermograph allows for detection of a temperature distribution and heat generation, In addition, the light-receiving device 1 is also applicable to electronic apparatuses that detect fire, water, gas, etc.

The embodiment and the application examples are described above, but the present disclosure contents are not limited to the foregoing embodiment, etc., and may be modified in a variety of ways. For example, the layer configuration of the light-receiving device described in the foregoing embodiment is merely exemplified, and any other layer may be further provided. In addition, the material and the thickness of each layer are also merely exemplified, and are not limited to the foregoing.

For example, in the foregoing embodiment, etc., description has been give of the case where the first electrode 21 and the first contact layer 22 are in contact with. each other and the second contact layer 24 and the second electrode 25 are in contact with each other, but any other layer may be provided between the first electrode 21 and the first contact layer 22 or between the second contact layer 24 and the second electrode 25.

Further, in the foregoing. embodiment, etc., the case where the signal charges are holes is described for convenience, but the signal charges may be electrons. The first contact layer 22 may include an n-type impurity, and the second contact layer 24 may include a p-type impurity.

Moreover, the effects described in the foregoing embodiment, etc. are merely exemplified, and may be any other effects or may further include any other effects.

It is to be noted that the present disclosure may have the following configurations.

(1) A light-receiving device including:
a plurality of photoelectric conversion layers including a first photoelectric conversion layer and a second photoelectric conversion layer disposed in respective regions that are different in a planar view;
an insulating film that separates the plurality of photoelectric conversion layers from one another;
a first inorganic semiconductor material included in the first photoelectric conversion layer; and
a second inorganic semiconductor material included in the second photoelectric conversion layer, and different from the first inorganic semiconductor material.

(2) The light-receiving device according to (1), in which a thickness of the first photoelectric conversion layer is different from a thickness of the second photoelectric conversion layer.

(3) The light-receiving device according to (1) or (2), further including a third photoelectric conversion layer provided in a thickness direction of the first photoelectric conversion layer, and overlapping a portion of the first photoelectric conversion layer in a planar view, in which
the third photoelectric conversion layer includes a third inorganic semiconductor material different from the first inorganic semiconductor material.

(4) The light-receiving device according to any one of (1) to (3), in which the first photoelectric conversion layer or the second photoelectric conversion layer or both are configured to generate electric charges through absorbing light of a wavelength in an infrared region.

(5) The light-receiving device according to any one of (1) to (4), in which the first photoelectric conversion layer or the second photoelectric conversion layer or both are configured to generate electric charges through absorbing light of a wavelength in a visible region.

(6) The light-receiving device according to any one of (1) to (5), in which the first inorganic semiconductor material or the second inorganic semiconductor material or both include one of Ge, InGaAs, ExInGaAs, InAsSb, InAs, InSb, and HgCdTe.

(7) The light-receiving device according to any one of (1) to (6), further including:
a first electrode electrically coupled to each of the first photoelectric conversion layer and the second photoelectric conversion layer; and
a ROIC (readout integrated circuit) substrate electrically coupled to each of the first electrodes.

(8) The light-receiving device according to (7), further including a first contact layer provided between the first electrode and each of the first photoelectric conversion layer and the second photoelectric conversion layer.

(9) The light-receiving device according to (8), in which surfaces in contact with the first electrodes of a plurality of the first contact layers are flush with one another.

(10) The light-receiving device according to any one of (7) to (9), further including a second electrode opposed to the first electrode with ach of the first photoelectric conversion layer and the second photoelectric conversion layer interposed therebetween.

(11) The light-receiving device according to (10), further including a second contact layer provided between the second electrode and each of the first photoelectric conversion layer and the second photoelectric conversion layer.

(12) The light-receiving device according to (11), in which surfaces in contact with the second electrode of a plurality of the second contact layers are flush with one another.

(13) The light-receiving device according to any one of (10) to (12), in which the second electrode is provided common to the first photoelectric conversion layer and the second photoelectric conversion layer.

(14) The light-receiving device according to any one of (1) to (13), in which a size of the first photoelectric conversion layer is different from a size of the second photoelectric conversion layer in a planar view.

(15) A method of manufacturing a light-receiving device, the method including:
of a plurality of photoelectric conversion layers disposed in respective regions that are different in a planar view, and separated from one another by an insulating film,
forming a first photoelectric conversion layer including a first inorganic semiconductor material; and
forming a second photoelectric conversion layer including a second inorganic semiconductor material different from the first inorganic semiconductor material.

(16) The method of manufacturing the light-receiving device according to (15), in which the first photoelectric conversion layer and the second photoelectric conversion layer are formed through
forming the insulating film having a first opening and a second opening on a substrate, and
epitaxially growing the first inorganic semiconductor material in the first opening, and the second inorganic semiconductor material in the second opening.

(17) The method of manufacturing the light-receiving device according to (16), in which a hard mask is used to cover each of the second opening in epitaxially growing the first inorganic semiconductor material in the first opening, and the first opening in epitaxially growing the second inorganic semiconductor material in the second opening.

(18) An imaging device including:
a plurality of photoelectric conversion layers including a first photoelectric conversion layer and a second photoelectric conversion layer disposed in respective regions that are different in a planar view;
an insulating film that separates the plurality of photoelectric conversion layers from one another;
a first inorganic semiconductor material included in the first photoelectric conversion layer; and
a second inorganic semiconductor material included in the second photoelectric conversion layer, and different from the first inorganic semiconductor material.

(19) An electronic apparatus provided with an imaging device, the imaging device including:
a plurality of photoelectric conversion layers including a first photoelectric conversion layer and a second photoelectric conversion layer disposed in respective regions that are different in a planar view;
an insulating film that separates the plurality of photoelectric conversion layers from one another;
a first inorganic semiconductor material included in the first photoelectric conversion layer; and
a second inorganic semiconductor material included in the second photoelectric conversion layer, and different from the first inorganic semiconductor material.

This application claims the benefit of Japanese Priority Patent Application JP2017-I0187 filed with the Japan Patent Office on Jan. 24, 2017, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof

What is claimed is:

1. A light-receiving device comprising:
a plurality of photoelectric conversion layers including a first photoelectric conversion layer and a second photoelectric conversion layer disposed in respective regions that are different in a planar view;
an insulating film that separates the plurality of photoelectric conversion layers from one another;
a first inorganic semiconductor material included in the first photoelectric conversion layer; and
a second inorganic semiconductor material included in the second photoelectric conversion layer, and different from the first inorganic semiconductor material.

2. The light-receiving device according to claim 1, wherein a thickness of the first photoelectric conversion layer is different from a thickness of the second photoelectric conversion layer.

3. The light-receiving device according to claim 1, further comprising a third photoelectric conversion layer provided in a thickness direction of the first photoelectric conversion layer, and overlapping a portion of the first photoelectric conversion layer in a planar view, wherein
the third photoelectric conversion layer includes a third inorganic semiconductor material different from the first inorganic semiconductor material.

4. The light-receiving device according to claim 1, wherein the first photoelectric conversion layer or the second photoelectric conversion layer or both are configured to generate electric charges through absorbing light of a wavelength in an infrared region.

5. The light-receiving device according to claim 1, wherein the first photoelectric conversion layer or the second photoelectric conversion layer or both are configured to generate electric charges through absorbing light of a wavelength in a visible region.

6. The light-receiving device according to claim 1, wherein the first inorganic semiconductor material or the second inorganic semiconductor material or both include one of Ge, InGaAs, Ex.InGaAs, InAsSb, InAs, InSb, and HgCdTe.

7. The light-receiving device according to claim 1, further comprising:
a first electrode electrically coupled to each of the first photoelectric conversion layer and the second photoelectric conversion layer; and
a ROIC (readout integrated circuit) substrate electrically coupled to each of the first electrodes.

8. The light-receiving device according to claim 7, further comprising a first contact layer provided between the first electrode and each of the first photoelectric conversion layer and the second photoelectric conversion layer.

9. The light-receiving device according to claim 8, wherein surfaces in contact with the first electrodes of a plurality of the first contact layers are flush with one another.

10. The light-receiving device according to claim 7, further comprising a second electrode opposed to the first electrode with each of the first photoelectric conversion layer and the second photoelectric conversion layer interposed therebetween.

11. The light-receiving device according to claim 10, further comprising a second contact layer provided between the second electrode and each of the first photoelectric conversion layer and the second photoelectric conversion layer.

12. The light-receiving device according to claim 11, wherein surfaces in contact with the second electrode of a plurality of the second contact layers are flush with one another.

13. The light-receiving device according to claim 10, wherein the second electrode is provided common to the first photoelectric conversion layer and the second photoelectric conversion layer.

14. The light-receiving device according to claim 1, wherein a size of the first photoelectric conversion layer is different from a size of the second photoelectric conversion layer in a planar view.

15. A method of manufacturing a light-receiving device, the method comprising:
of a plurality of photoelectric conversion layers disposed in respective regions that are different in a planar view, and separated from one another by an insulating film, forming a first photoelectric conversion layer including a first inorganic semiconductor material; and
forming a second photoelectric conversion layer including a second inorganic semiconductor material different from the first inorganic semiconductor material.

16. The method of manufacturing the light-receiving device according to claim 15, wherein the first photoelectric conversion layer and the second photoelectric conversion layer are formed through
forming the insulating film having a first opening and a second opening on a substrate, and
epitaxially growing the first inorganic semiconductor material in the first opening, and the second inorganic semiconductor material in the second opening.

17. The method of manufacturing the light-receiving device according to claim 16, wherein a hard mask is used to cover each of the second opening in epitaxially growing the first inorganic semiconductor material in the first opening, and the first opening in epitaxially growing the second inorganic semiconductor material in the second opening.

18. An imaging device comprising:
a plurality of photoelectric conversion layers including a first photoelectric conversion layer and a second photoelectric conversion layer disposed in respective regions that are different in a planar view;
an insulating film that separates the plurality of photoelectric conversion layers from one another;
a first inorganic semiconductor material included in the first photoelectric conversion layer; and
a second inorganic semiconductor material included in the second photoelectric conversion layer, and different from the first inorganic semiconductor material.

19. An electronic apparatus provided with an imaging device, the imaging device comprising:
a plurality of photoelectric conversion layers including a first photoelectric conversion layer and a second photoelectric conversion layer disposed in respective regions that are different in a planar view;
an insulating film that separates the plurality of photoelectric conversion layers from one another;
a first inorganic semiconductor material included in the first photoelectric conversion layer; and
a second inorganic semiconductor material included in the second photoelectric conversion layer, and different from the first inorganic semiconductor material.
